(19) United States
(12) Patent Application Publication
(10) Pub. No.: US 2019/0296043 A1
(43) Pub. Date: Sep. 26, 2019

(54) MEMORY DEVICE

(71) Applicant: TOSHIBA MEMORY CORPORATION, Minato-ku (JP)

(72) Inventor: Yusuke OKUMURA, Yokkaichi (JP)

(73) Assignee: TOSHIBA MEMORY CORPORATION, Minato-ku (JP)

(21) Appl. No.: 16/128,646

(22) Filed: Sep. 12, 2018

(30) Foreign Application Priority Data
Mar. 20, 2018 (JP) 2018-053265

(51) Int. Cl. H01L 27/11582; H01L 29/06

(52) U.S. Cl. CPC H01L 27/11582; H01L 29/0657

(57) ABSTRACT

A memory device includes a plurality of first electrode layers stacked in a first direction; a plurality of second electrode layers stacked in the first direction and provided in the first direction when viewed from the plurality of first electrode layers; a first columnar body extending in the first direction and piercing the plurality of first electrode layers and the plurality of second electrode layers; a second columnar body extending in the first direction and piercing the plurality of first electrode layers; and a third columnar body extending in the first direction, piercing at least one of the plurality of second electrode layers, and being connected to an end of the second columnar body. The first columnar body includes a first semiconductor layer extending in the first direction. The third columnar body includes a material different from a material of the second columnar body.

### CROSS-REFERENCE TO RELATED APPLICATIONS

This application is based upon and claims the benefit of priority from Japanese Patent Application No. 2018-053265, filed on Mar. 20, 2018; the entire contents of which are incorporated herein by reference.

### FIELD

Embodiments relate to a memory device.

### BACKGROUND

A memory device that includes three-dimensionally arranged memory cells is being developed. For example, a NAND nonvolatile memory device includes multiple electrode layers stacked on a source layer, and a semiconductor layer provided in the interior of a memory hole piercing the multiple electrode layers in the stacking direction. The memory cells are disposed respectively at the portions where the electrode layers cross the semiconductor layer extending in the stacking direction of the electrode layers. When the number of stacks of electrode layers is increased to increase the memory capacity of such a memory device, it becomes difficult to form the memory hole. Also, it becomes difficult to form the electrode layers and contact plugs that connect the electrode layers to interconnects.

### BRIEF DESCRIPTION OF THE DRAWINGS

FIG. 1 is a perspective view schematically showing a memory device according to an embodiment;

FIGS. 2A and 2B are partial cross-sectional views schematically showing the memory device according to the embodiment; and

FIGS. 3A to 11B are schematic cross-sectional views showing the manufacturing process of the memory device according to the embodiment.

### DETAILED DESCRIPTION

According to one embodiment, a memory device includes a plurality of first electrode layers stacked in a first direction; a plurality of second electrode layers stacked in the first direction and provided in the first direction when viewed from the plurality of first electrode layers; a first columnar body extending in the first direction and piercing the plurality of first electrode layers and the plurality of second electrode layers; a second columnar body extending in the first direction and piercing the plurality of first electrode layers; and a third columnar body extending in the first direction, piercing at least one of the plurality of second electrode layers, and being connected to an end of the second columnar body. The first columnar body includes a first semiconductor layer extending in the first direction. The third columnar body includes a material different from a material of the second columnar body.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

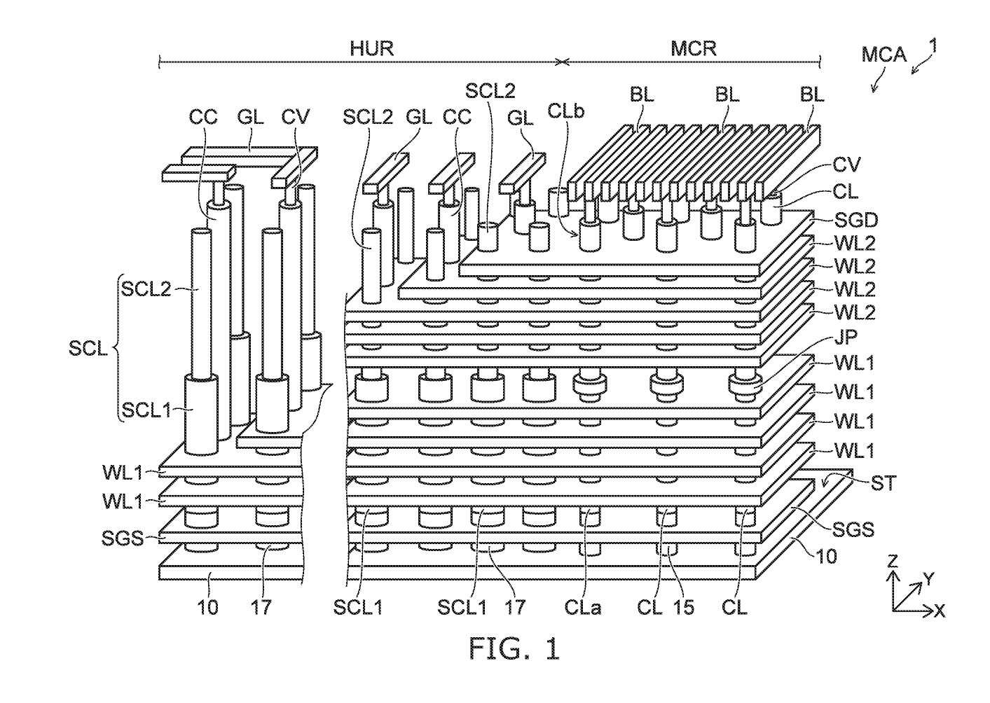

FIG. 1 is a perspective view schematically showing a memory device 1 according to an embodiment. The memory device 1 is, for example, a NAND nonvolatile memory device and includes a memory cell array MCA including three-dimensionally arranged memory cells. In FIG. 1, insulating films that electrically insulate between the components are not illustrated for convenience.

As shown in FIG. 1, the memory cell array MCA includes multiple electrode layers stacked above a source layer 10. The multiple electrode layers include, for example, a select gate SGS, multiple word lines WL1, multiple word lines WL2, and a select gate SGD. In the description hereinbelow, there are cases where the electrode layers are described individually and cases where the electrode layers are described generally. The other components also are described similarly. The number of stacks of the word lines WL1 and WL2 shown in FIG. 1 are displayed as being fewer than the actual number of stacks in the memory device.

The multiple electrode layers each extend in an X-direction. Other not-illustrated electrode layers are arranged in a Y-direction. A slit ST is provided between the electrode layers arranged in the Y-direction to define the outer edges of the electrode layers.

The memory cell array MCA includes a memory cell region MCR and a draw-out region HUR. The memory cell region MCR includes multiple columnar bodies CL. The columnar bodies CL extend in a Z-direction and pierce the word lines WL1 and WL2 and the select gate SGD. The columnar bodies CL include a first columnar portion CLa, a second columnar portion CLb, and a connection portion JP. The first columnar portion CLa pierces the word lines WL1 and extends in the Z-direction; and the second columnar portion CLb pierces the word lines WL2 and extends in the Z-direction.

The connection portion JP is provided between the first columnar portion CLa and the second columnar portion CLb. The size of the connection portion JP in the horizontal direction (the X-direction and the Y-direction) is larger than those of the first columnar portion CLa and the second columnar portion CLb. In other words, the widths in the X-direction/Y-direction of the connection portion JP at the portions of the first columnar portion CLa and the second columnar portion CLb linked to the connection portion JP are wider than the width in the X-direction/Y-direction of the first columnar portion CLa and the width in the X-direction/Y-direction of the second columnar portion CLb.

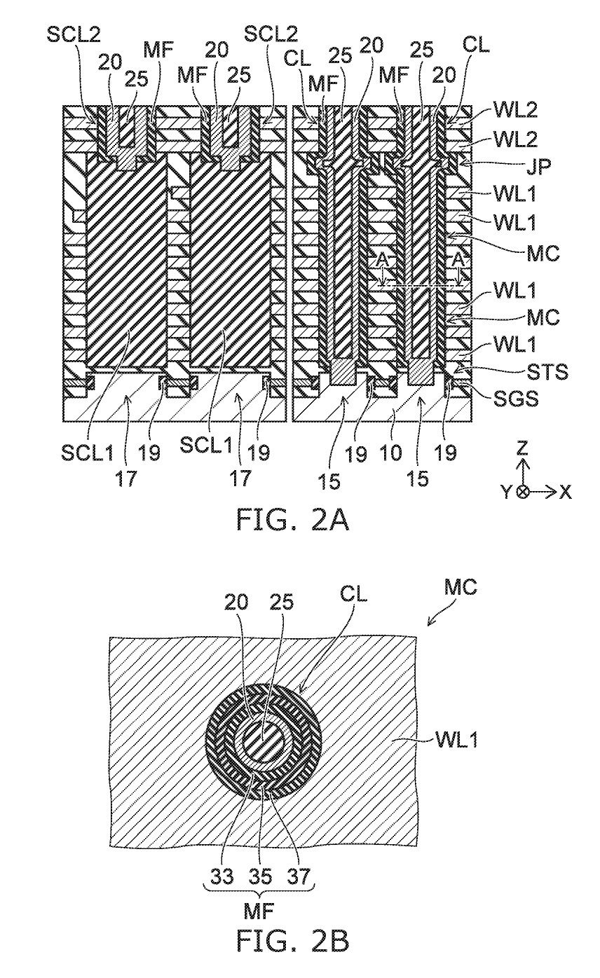

The memory cell region MCR further includes a semiconductor layer 15. The semiconductor layer 15 is provided between the source layer 10 and the columnar body CL. The semiconductor layer 15 is provided to pierce the select gate SGS in the Z-direction. The columnar body CL includes a not-illustrated semiconductor layer 20 (referring to FIG. 2A); and the lower end of the semiconductor layer 20 is electrically connected to the source layer 10 via the semiconductor layer 15. The semiconductor layer 20 is electrically connected to a bit line BL via a connection plug CV connected to the upper end of the semiconductor layer 20.

The draw-out region HUR is provided at ends of the electrode layers extending in the X-direction. In the draw-out region HUR, the ends of the electrode layers are provided in a staircase configuration. The draw-out region HUR includes multiple columnar support bodies SCL1 and multiple columnar support bodies SCL2; and ends of the multiple columnar support bodies SCL1 are connected respectively to ends of the multiple columnar support bodies SCL2. Although the connection portion JP is provided between the first columnar portion CLa and the second columnar portion CLb in the columnar bodies CL included in the memory cell region MCR, the columnar support body SCL1 on the lower layer side and the columnar support body SCL2 on the upper layer side are directly connected in the columnar support bodies SCL included in the draw-out region HUR.

The columnar support bodies SCL1 each are provided to pierce at least one word line WL1 in the Z-direction. The columnar support bodies SCL2 are provided on the columnar support bodies SCL1; and some of the columnar support bodies SCL2 are provided to pierce the word lines WL2 and the select gate SGD in the Z-direction. Another portion of the columnar support bodies SCL2 includes columnar support bodies SCL2 that do not pierce the select gate SGD but pierce at least one of the word lines WL2, and columnar support bodies SCL2 that do not pierce any of the electrode layers. Here, the columnar support body SCL1 that is connected to a columnar support body SCL2 piercing at least one of the word lines WL2 is provided to pierce all of the word lines WL1 in the Z-direction. On the other hand, a columnar support body SCL2 that does not pierce any of the electrode layers and pierces a not-illustrated insulating film formed on the electrode layers of the staircase configuration in the Z-direction is disposed on a columnar support body SCL1 that pierces only some of the word lines WL1 and does not pierce all of the word lines WL1 in the Z-direction. Thus, the columnar support bodies SCL2 may not be disposed on the columnar support bodies SCL1 that pierce only some of the word lines WL1.

The end surface of the columnar support body SCL1 has a wider surface area than the end surface of the columnar support body SCL2 at the portion where the columnar support body SCL1 and the columnar support body SCL2 are linked. For example, the width in the X-direction/Y-direction of the upper end of the columnar support body SCL1 is wider than the width in the X-direction/Y-direction of the lower end of the columnar support body SCL2.

The draw-out region HUR further includes semiconductor layers 17 and contact plugs CC. The semiconductor layers 17 are provided between the source layer 10 and the columnar support bodies SCL1 and pierce the select gate SGS in the Z-direction. For example, the contact plugs CC extend in the Z-direction through the not-illustrated insulating film formed on the electrode layers of the staircase configuration and are connected to the end portions of the electrode layers having the staircase configuration. The contact plugs CC are electrically connected to interconnects GL of an upper layer via other connection plugs CV. The contact plugs CC electrically connect the electrode layers to the interconnects GL of the upper layer.

FIGS. 2A and 2B are partial cross-sectional views schematically showing the memory device 1 according to the embodiment. FIG. 2A is a schematic view showing a cross section of the columnar bodies CL and the columnar support bodies SCL1 and SCL2. FIG. 2B is a schematic view showing a cross section along line A-A shown in FIG. 2A and illustrates the structure of a memory cell MC.

As shown in FIG. 2A, the columnar body CL includes a memory film MF, the semiconductor layer 20, and an insulating core 25. The insulating core 25 is provided to extend in the Z-direction. The insulating core 25 includes, for example, silicon oxide. The semiconductor layer 20 is provided to surround the insulating core 25. The semiconductor layer 20 is connected to the semiconductor layer 15 at the lower end of the semiconductor layer 20. The memory film MF is positioned at the outermost shell of the columnar body CL.

The memory cell MC is provided at each portion where the semiconductor layer 20 crosses the word lines WL1 and WL2. A select transistor STS is provided at the portion where the semiconductor layer 15 pierces the select gate SGS. A gate insulating film 19 is provided between the semiconductor layer 15 and the select gate SGS. A not-illustrated select transistor STD is provided at the portion where the semiconductor layer 20 pierces the select gate SGD (referring to FIG. 1).

The columnar support body SCL1 is, for example, an insulating body extending in the Z-direction. The columnar support body SCL1 includes, for example, an insulative metal oxide or silicon oxide. On the other hand, the columnar support body SCL2 includes the memory film MF, the semiconductor layer 20, and the insulating core 25.

As shown in FIG. 2B, the semiconductor layer 20 is provided to surround the insulating core 25. The semiconductor layer 20 is, for example, a polysilicon layer. The memory film MF is provided to surround the semiconductor layer 20 between the semiconductor layer 20 and the word lines WL1 (or WL2).

The memory film MF includes, for example, a tunneling insulating film 33, a charge storing film 35, and a blocking insulating film 37. The tunneling insulating film 33, the charge storing film 35, and the blocking insulating film 37 have a structure of being stacked in order in the direction from the semiconductor layer 20 toward the word line WL1.

The tunneling insulating film 33 and the blocking insulating film 37 are, for example, silicon oxide films. The charge storing film 35 is, for example, a silicon nitride film. The memory film MF may include a high dielectric constant film such as an aluminum oxide film or the like between the blocking insulating film 37 and the word line WL1. In other words, the blocking insulating film 37 may have a structure in which a silicon oxide film and a high dielectric constant film are stacked.

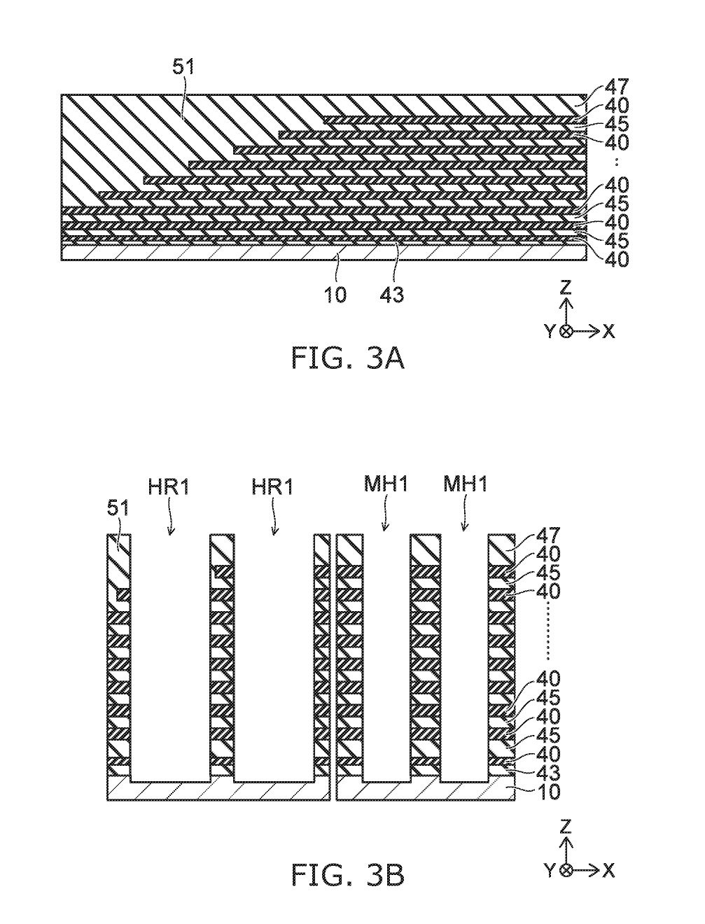

A method for manufacturing the memory device 1 will now be described with reference to FIG. 3A to FIG. 11B. FIG. 3A to FIG. 11B are schematic cross-sectional views showing the manufacturing process of the memory device according to the embodiment in order.

As shown in FIG. 3A, sacrificial films 40 and insulating films 45 are stacked alternately, with an insulating film 43 interposed, on the source layer 10. An insulating film 47 is provided on the sacrificial film 40 of the uppermost layer. The source layer 10 is, for example, a P-type well provided in the surface layer of a silicon substrate or is a polysilicon layer provided on a silicon substrate with an insulating film interposed. The sacrificial films 40 are, for example, silicon nitride films; and the insulating films 43, 45, and 47 are, for example, silicon oxide films.

Continuing, the ends of the sacrificial films 40 and the insulating films 45 are patterned into a staircase configuration; subsequently, an insulating film 51 is formed to cover the end portions of the sacrificial films 40 and the insulating films 45. The insulating film 51 is, for example, a silicon oxide film and is formed to surround the region used to form the memory cell array MCA. The insulating film 51 is formed so that the upper surface of the insulating film 51 is positioned at substantially the same level as the upper surface of the insulating film 47.

As shown in FIG. 3B, memory holes MH1 are formed in the region used to form the memory cell region MCR; and holes HR1 are formed in the region used to form the draw-out region HUR. The memory holes MH1 have depths that reach the source layer 10 from the upper surface of the insulating film 47; and the holes HR1 have depths that reach the source layer 10 from the upper surface of the insulating film 51. The memory holes MH1 are formed so that the opening surface areas of the memory holes MH1 are narrower than the opening surface areas of the holes HR1.

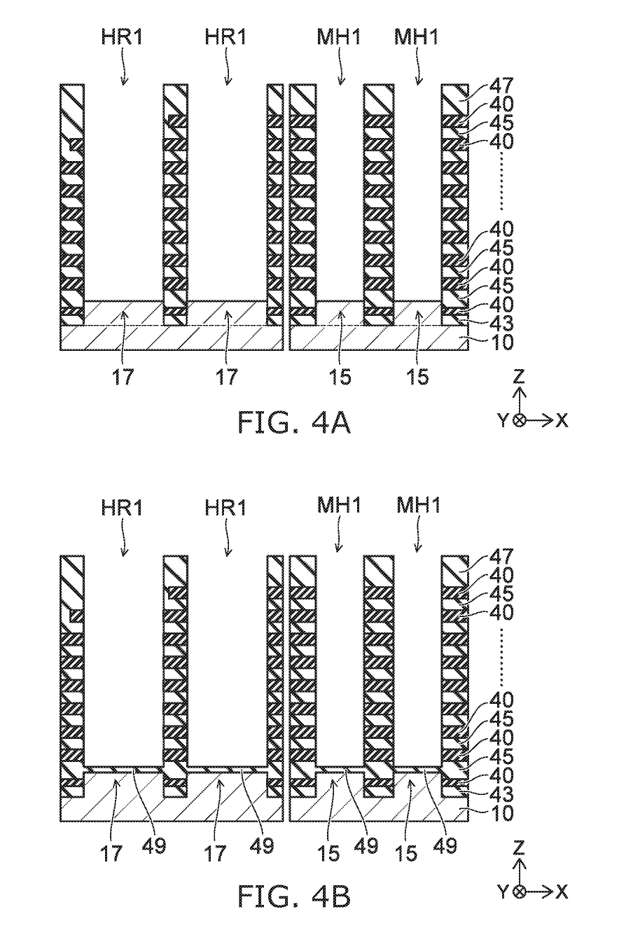

As shown in FIG. 4A, the semiconductor layers 15 and 17 are formed respectively on the bottom surfaces of the memory hole MH1 and the hole HR1. The semiconductor layers 15 and 17 are, for example, silicon layers and are epitaxially grown on the source layer 10 exposed at the bottom surfaces of the memory hole MH1 and the hole HR1. The semiconductor layers 15 and 17 are formed so that the upper surfaces of the semiconductor layers 15 and 17 are positioned at levels between the sacrificial film 40 of the lowermost layer and the sacrificial film 40 positioned directly above the sacrificial film 40 of the lowermost layer.

As shown in FIG. 4B, an insulating film 49 is formed on the semiconductor layer 15 and the semiconductor layer 17. For example, the insulating film 49 is formed by performing thermal oxidation of the semiconductor layers 15 and 17.

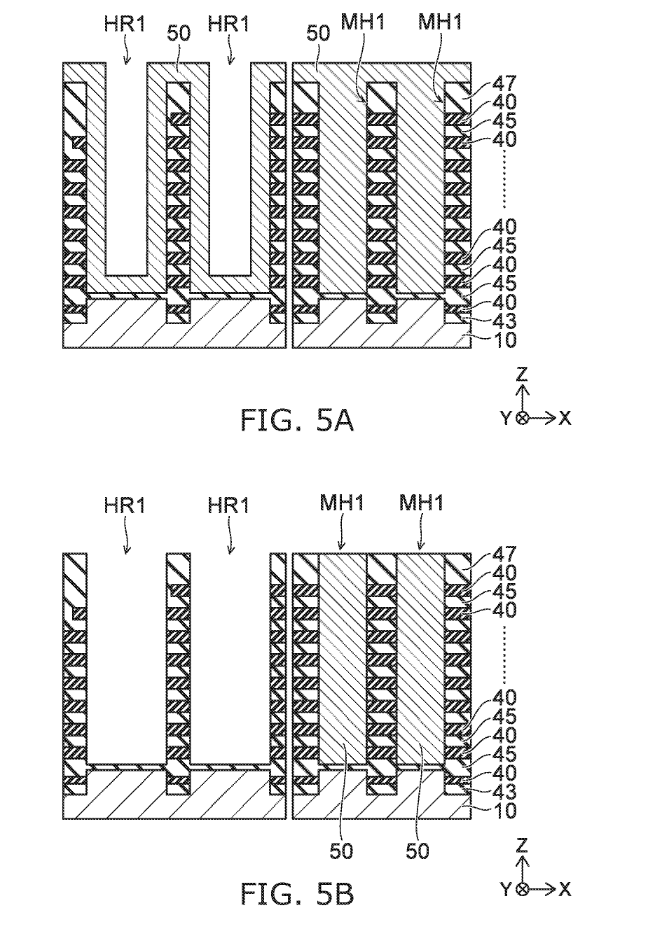

As shown in FIG. 5A, a sacrificial film 50 is formed to fill the interior of the memory hole MH1 and cover the inner surface of the hole HR1. The sacrificial film 50 is, for example, an amorphous silicon film. By, for example, using CVD (Chemical Vapor Deposition), the sacrificial film 50 is formed to have a thickness that fills the interior of the memory hole MH1 and causes a space to remain inside the hole HR1.

As shown in FIG. 5B, the sacrificial film 50 is selectively removed so that the portion filling the memory hole MH1 remains and the portion covering the inner surface of the hole HR1 is removed. For example, the sacrificial film 50 is removed under isotropic etching conditions.

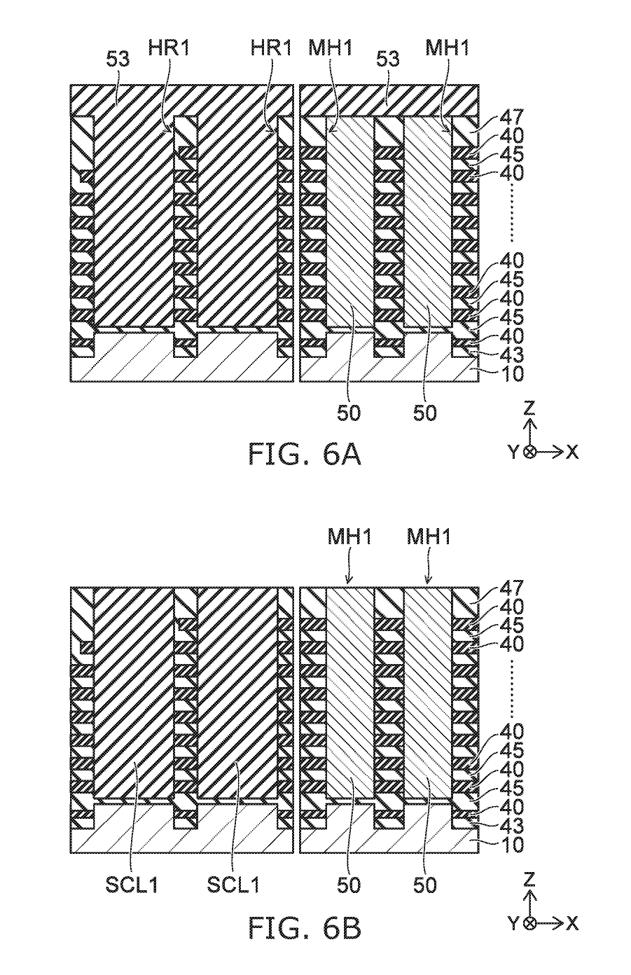

As shown in FIG. 6A, an insulating film 53 is formed to fill the interior of the hole HR1. The insulating film 53 is, for example, a silicon oxide film or a metal oxide film of hafnium oxide, aluminum oxide, etc.

As shown in FIG. 6B, etch-back of the insulating film 53 is performed so that the portion formed at a level higher than the upper surface of the insulating film 47 is removed; and the upper surface of the sacrificial film 50 is exposed. For example, the etch-back of the insulating film 53 is performed using isotropic dry etching. Thereby, the columnar support body SCL1 is formed inside the hole HR1.

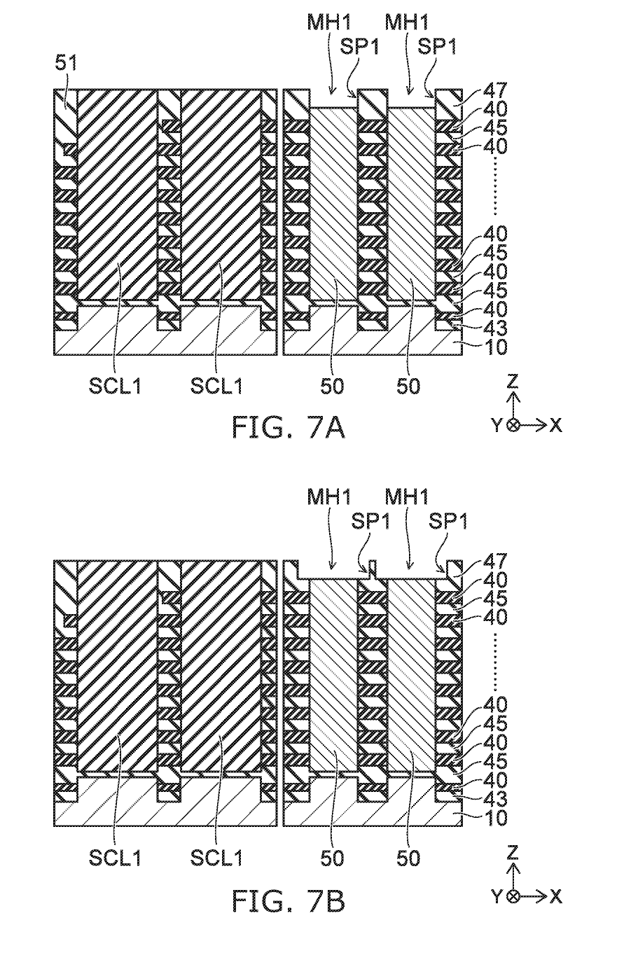

As shown in FIG. 7A, etch-back of a portion of the sacrificial film 50 is performed selectively; and a space SP1 is formed in the upper portion of the memory hole MH1. The sacrificial film 50 is selectively removed using etching conditions for which the insulating films 47 and 51 and the columnar support body SCL1 have resistance.

As shown in FIG. 7B, the space SP1 is enlarged in the horizontal direction (the X-direction and the Y-direction) by partially removing the insulating film 47. For example, the insulating film 47 is removed by isotropic etching.

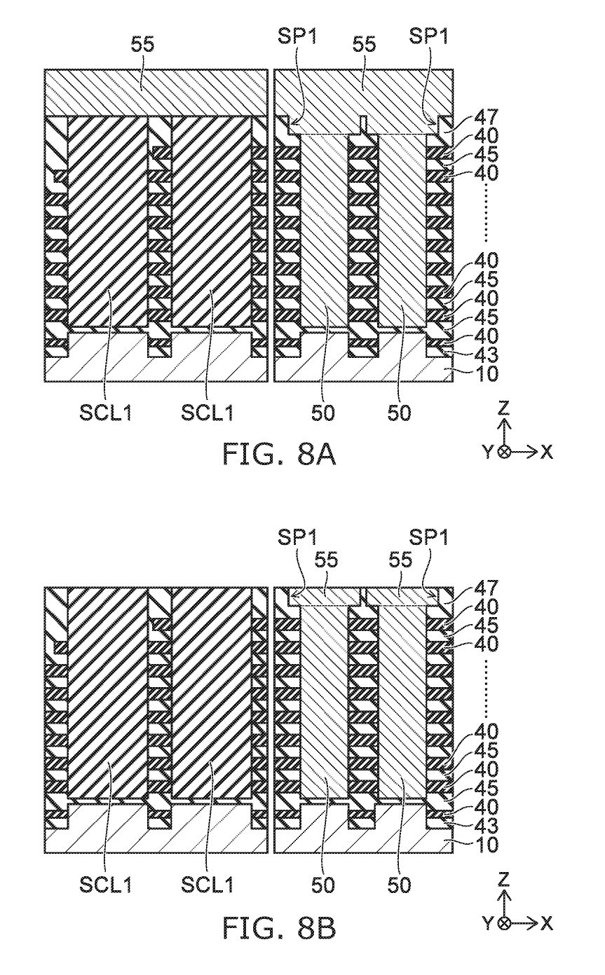

As shown in FIG. 8A, a sacrificial film 55 is formed to fill the space SP1. The sacrificial film 55 is, for example, an amorphous silicon film.

As shown in FIG. 8B, the portion of the sacrificial film 55 formed at a level higher than the upper surfaces of the insulating films 47 and 51 is removed. For example, the sacrificial film 55 is removed using CMP (Chemical Mechanical Polishing). Thereby, the portion of the sacrificial film 55 filling the space SP1 remains; and the upper surface of the columnar support body SCL1 is exposed.

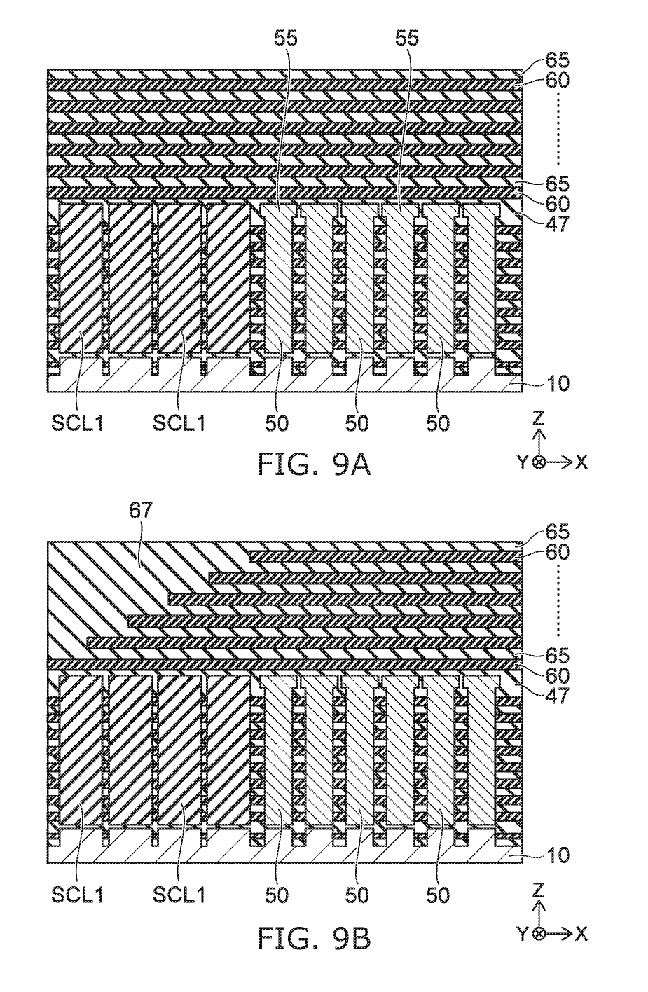

As shown in FIG. 9A, sacrificial films 60 and insulating films 65 are stacked alternately on the sacrificial film 55 and the columnar support body SCL1. The sacrificial films 60 are, for example, silicon nitride films; and the insulating films 65 are, for example, silicon oxide films.

As shown in FIG. 9B, the end portions of the sacrificial films 60 and the insulating films 65 are formed in a staircase configuration; subsequently, an insulating film 67 is formed to cover the end portions of the sacrificial films 60 and the insulating films 65. The insulating film 67 is, for example, a silicon oxide film.

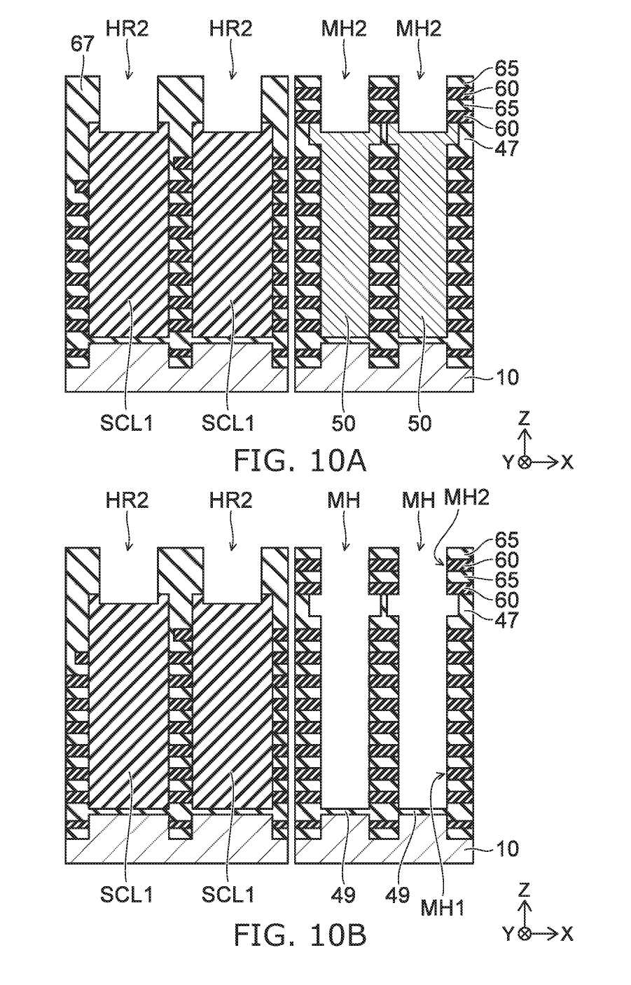

A memory hole MH2 and a hole HR2 are formed as shown in FIG. 10A. The memory hole MH2 is formed to communicate with the sacrificial film 55 in the region used to form the memory cell region MCR. The hole HR2 is formed to communicate with the columnar support body SCL1 in the region used to form the draw-out region HUR. The memory hole MH2 has a depth that reaches the sacrificial film 55 from the upper surface of the insulating film 65 of the uppermost layer (referring to FIG. 9B). The memory hole MH2 is formed to have a bottom surface that is narrower than the upper surface of the sacrificial film 55. Thereby, the tolerance of the positional alignment of the memory hole MH2 with respect to the memory hole MH1 can be ensured.

The hole HR2 has a depth that reaches the columnar support body SCL1 from the upper surface of the insulating film 67. The hole HR2 is formed to have a bottom surface that is narrower than the surface area of the upper surface of the columnar support body SCL1.

As shown in FIG. 10B, the sacrificial films 50 and 55 that fill the interior of the memory hole MH1 are selectively removed. For example, the sacrificial films 50 and 55 are selectively removed using etching conditions for which the silicon oxide film and the silicon nitride film have resistance. Thereby, a memory hole MH can be formed in which the memory hole MH1 and the memory hole MH2 are linked as one body.

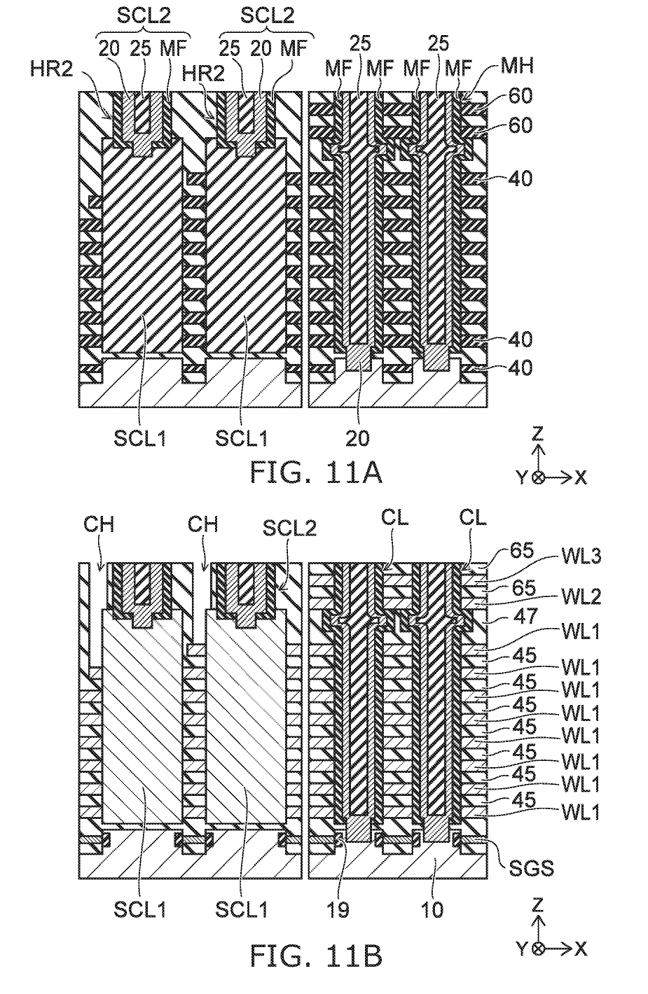

As shown in FIG. 11A, the memory film MF, the semiconductor layer 20, and the insulating core 25 are formed in the interiors of the memory hole MH and the hole HR2. The semiconductor layer 20 is formed to contact the semiconductor layer 15 at the bottom surface of the memory hole MH. Also, the semiconductor layer 20 is formed to contact the columnar support body SCL1 at the bottom surface of the hole HR2.

As shown in FIG. 11B, the select gate SGS, the word lines WL1, the word lines WL2, and the select gate SGD are formed by replacing the sacrificial films 40 and the sacrificial films 60 with metal layers.

For example, the sacrificial films 40 and 60 are selectively removed by supplying an etchant via the not-illustrated slit ST (referring to FIG. 1). Thereby, spaces are formed between the insulating films 45 and between the insulating films 65. The spaces are maintained by the columnar bodies CL and the columnar support bodies SCL supporting the insulating films 45 and the insulating films 65.

The gate insulating films 19 are formed by performing thermal oxidation of the side surfaces of the semiconductor layers 15 and 17 in the space where the sacrificial film 40 of the lowermost layer is removed. Subsequently, a metal layer is deposited using CVD in the spaces where the sacrificial films 40 and the sacrificial films 60 are removed. Thereby, the sacrificial films 40 and the sacrificial films 60 can be replaced with electrode layers. In the draw-out region HUR, contact holes CH that communicate with the end portions of the electrode layers are formed; and the contact plugs CC are formed in the interiors of the contact holes CH.

In the embodiment as shown in FIG. 3B and FIG. 10A, the memory hole MH1 and the memory hole MH2 are formed in separate processes; subsequently, the memory hole MH can be realized in which the memory hole MH1 and the memory hole MH2 are formed as one body to have a large aspect ratio by selectively removing the sacrificial films 50 and 55. However, for the memory hole MH1 and the hole HR1 that are formed in the same process as the memory hole MH1, if a deficiency exists in the insulating film 49 formed at the bottom surfaces of the memory hole MH1 and the hole HR1, there are cases where the semiconductor layer 15 is etched and a void occurs when selectively removing the sacrificial film 50. As a result, a metal layer is deposited also inside the void when forming the select gate SGS by replacing the sacrificial film 40 with the metal layer; and a short may occur between the select gate SGS and the semiconductor layers 15 and 17.

Such a discrepancy occurs more markedly in the hole HR1 which has a large opening diameter and causes the manufacturing yield to decrease. Conversely, in the memory device 1, the columnar support body SCL1 is formed inside the hole HR1 instead of the sacrificial film 50. Thereby, the etching of the semiconductor layer 17 can be avoided (referring to FIG. 10B).

Also, the columnar support body SCL1 has a configuration that does not include a conductive body such as the semiconductor layer 20 or the like. Therefore, even in the case where interference occurs between the columnar support body SCL1 and the contact holes CH communicating with the electrode layers where the sacrificial films 40 are replaced (referring to FIG. 11B), the structure is such that a short does not occur between the contact plugs CC and a conductive body.

For example, the columnar support body SCL1 includes a material that has resistance to the etching conditions when selectively removing the sacrificial films 40 and the sacrificial films 60. Further, it is desirable for the material to have resistance to the etching conditions when forming the contact holes CH, i.e., the etching conditions of the insulating film 51 (referring to FIG. 3A) and the insulating film 67 (referring to FIG. 9B). For example, by using hafnium oxide or aluminum oxide as the columnar support body SCL1, the contact holes CH can be formed without extending through the electrode layers; and shorts between the electrode layers via the contact plugs CC can be avoided.

The columnar support body SCL1 and the columnar support body SCL2 are directly connected; and a portion that corresponds to the connection portion JP is not provided between the columnar support body SCL1 and the columnar support body SCL2. In other words, the columnar support body SCL does not have a portion enlarged in the horizontal direction; and the tolerance of the positional alignment between the contact plug CC and the columnar support body SCL can be large.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory device, comprising:
a plurality of first electrode layers stacked in a first direction;
a plurality of second electrode layers stacked in the first direction and provided in the first direction when viewed from the plurality of first electrode layers;
a first columnar body extending in the first direction and piercing the plurality of first electrode layers and the plurality of second electrode layers;
a second columnar body extending in the first direction and piercing the plurality of first electrode layers; and
a third columnar body extending in the first direction, piercing at least one of the plurality of second electrode layers, and being connected to an end of the second columnar body,
the first columnar body including a first semiconductor layer extending in the first direction,
the third columnar body including a material different from a material of the second columnar body.

2. The device according to claim 1, further comprising:
a conductive layer electrically connected to an end of the first semiconductor layer; and
a first interconnect electrically connected to another end of the first semiconductor layer,
the plurality of first electrode layers and the plurality of second electrode layers being positioned between the conductive layer and the first interconnect,
the plurality of first electrode layers being positioned between the conductive layer and the plurality of second electrode layers.

3. The device according to claim 2, wherein
the third columnar body includes a second semiconductor layer extending in the first direction, and
the second columnar body does not include a semiconductor layer.

4. The device according to claim 3, wherein the second semiconductor layer is electrically insulated from the conductive layer.

5. The device according to claim 1, wherein the second columnar body includes an insulative metal oxide.

6. The device according to claim 2, further comprising:
a third semiconductor layer provided between the first columnar body and the conductive layer; and
a fourth semiconductor layer provided between the second columnar body and the conductive layer,
the first semiconductor layer being connected to the third semiconductor layer,
the third semiconductor layer being connected to the conductive layer.

7. The device according to claim 6, further comprising an insulating film provided between the second columnar body and the fourth semiconductor layer.

8. The device according to claim 7, wherein
the second columnar body includes an insulating body extending in the first direction, and
the third columnar body is connected to the insulating body.

9. The device according to claim 8, wherein the second columnar body includes the insulating body of a material different from a material of the insulating film.

10. The device according to claim 1, further comprising a contact plug extending in the first direction at a vicinity of the third columnar body and being connected to one of the plurality of first electrode layers or one of the plurality of second electrode layers.

11. The device according to claim 10, wherein
end portions of the plurality of first electrode layers and end portions of the plurality of second electrode layers are provided in a staircase configuration, and
the contact plug is connected to one of the end portions provided in the staircase configuration.

12. The device according to claim 1, wherein the first columnar body includes a first columnar portion, a second columnar portion, and a connection portion, the first columnar portion piercing the plurality of first electrode layers, the second columnar portion piercing the plurality of second electrode layers, the connection portion linking the first columnar portion and the second columnar portion.

13. The device according to claim 12, wherein a width in a second direction crossing the first direction of the connection portion is wider than a width in the second direction of a portion of the first columnar portion linked to the connection portion and wider than a width in the second direction of a portion of the second columnar portion linked to the connection portion.

14. The device according to claim 13, wherein a width in the second direction of the end of the second columnar body linked to the third columnar body is wider than a width in the second direction of an end of the third columnar body linked to the second columnar body.

15. The device according to claim 13, wherein the first columnar portion of the first columnar body has a width in the second direction narrower than a width in the second direction of the second columnar body.

16. A memory device, comprising:
a plurality of first electrode layers stacked in a first direction;
a plurality of second electrode layers stacked in the first direction and provided in the first direction when viewed from the plurality of first electrode layers;
a first columnar body extending in the first direction, piercing the plurality of first electrode layers and the plurality of second electrode layers, and including a first columnar portion, a second columnar portion, and a connection portion, the first columnar portion piercing the plurality of first electrode layers, the second columnar portion piercing the plurality of second electrode layers, the connection portion linking the first columnar portion and the second columnar portion;
a second columnar body extending in the first direction and piercing at least one of the plurality of first electrode layers; and
a third columnar body connected to an end of the second columnar body, the third columnar body extending in the first direction at a position separated from the plurality of second electrode layers,
the first columnar body including a first semiconductor layer extending in the first direction,
the third columnar body including a material different from a material of the second columnar body.

17. The device according to claim 16, further comprising a conductive layer electrically connected to an end of the first semiconductor layer,
the plurality of first electrode layers being positioned between the conductive layer and the plurality of second electrode layers,
end portions of the plurality of first electrode layers and end portions of the plurality of second electrode layers being provided in a staircase configuration,
the second columnar body extending in the first direction and piercing a first electrode layer of the plurality of first electrode layers most proximal to the conductive layer.

18. The device according to claim 17, further comprising an insulating layer covering the end portions of the plurality of first electrode layers and the end portions of the plurality of second electrode layers,
the third columnar body extending through the insulating layer in the first direction.

19. The device according to claim 16, wherein the end of the second columnar body is positioned at substantially the same level as an upper surface of the connection portion of the first columnar body in the first direction.

20. The device according to claim 16, wherein
the second columnar body includes an insulating body extending in the first direction, and
the third columnar body is connected to the insulating body.
